(19) United States
(12) Patent Application Publication
(10) Pub. No.: US 2026/0314077 A1
(43) Pub. Date: Oct. 8, 2026

(54) LAYOUT STRUCTURE OF STATIC RANDOM ACCESS MEMORY

(71) Applicant: SHANGHAI HUAHONG GRACE SEMICONDUCTOR MANUFACTURING CORPORATION, Shanghai (CN)

(72) Inventors: Tao YU, Shanghai (CN); Weiran KONG, Shanghai (CN)

(21) Appl. No.: 19/482,072

(22) PCT Filed: Dec. 14, 2023
(86) PCT No.: PCT/CN2023/138656

§ 371 Date: Nov. 6, 2025

(30) Foreign Application Priority Data
Oct. 30, 2023 (CN) 202311421395.8

(51) Int. Cl. H10D 89/10; H10B 10/00

(52) U.S. Cl. CPC H10D 89/10; H10B 10/12

(57) ABSTRACT

The present invention provides a SRAM layout structure including: first and second active areas both extending perpendicular to a horizontal direction; a gate of a first PD transistor on the first active area, which has a first gate portion perpendicular to the direction of extension of the first active area and a second gate portion extending at an angle less than 180° clockwise with respect to the first gate portion; and a gate of a second PD transistor on the second active area, which has a first gate portion perpendicular to the direction of extension of the second active area and a second gate portion extending at an angle less than 180° clockwise with respect to the first gate portion. The second gate portions of the second and first PD transistors oppose each other, and are spaced apart from each other at a distance, which satisfies a photolithography requirement. With the present invention, a smaller SRAM area can be achieved while satisfying the photolithography requirement, without reducing any gate length.

### TECHNICAL FIELD

The present invention relates to the field of semiconductor technology and, in particular, to a static random access memory (SRAM) layout structure.

### BACKGROUND

With the continual development of modern high-tech industries, as represented by electronic communication, the total revenue of the global integrated circuit market is growing by over 30% on a yearly basis. As an important type of memory to digital and communication circuits, static random access memory (SRAM) is widely used in the design of such circuits. SRAM is crucial for logic circuits and has found extensive use in data storage because of its advantages such as low power consumption and fast reading. A SRAM device may include an array of SRAM cells each including at least one pass-gate (PG) transistor, at least one pull-down (PD) transistor and at least one pull-up (PU) transistor.

Referring to FIG. 1, a portion of a conventional static random access memory (SRAM) layout structure includes one or more active areas and PD, PG and PU transistors on the active areas. The numbers of the PD, PG and PU transistors depends on the fabrication processes used. The PD and PG transistors are spaced from each other, while the PD and PU transistors may be made in contact. In the case of more than one active area, these may be isolated by shallow trench isolation (STI) structure(s). For example, there may be two active areas, a first active area 110 and a second active area 120, which both extend perpendicular to a horizontal direction. Each of the first active area 110 and the second active area 120 may be designed with a plurality of PD transistors, each with a gate thereof being located on the active area. For example, gates 130 of respective first PD transistors may be designed on the first active area 110 as elongate bars extending radially perpendicular to the first active area 110, and gates 140 of respective second PD transistors on the second active area 120 as elongate bars extending radially perpendicular to the second active area 120. The gates 130 of the first PD transistors and the gates 140 of the second PD transistors may be arranged in opposition, with a distance being left therebetween, which is minimized as much as permitted by the photolithography process used.

However, reducing the area of the conventional SRAM layout structure, particularly its horizontal dimension, requires reducing extensions of the gates 130 of the first PD transistors and/or the gates 140 of the second PD transistors beyond the first active area 110 and/or the second active area 120, or reducing the horizontal distance between the gates 130 of the first PD transistors and the gates 140 of the second PD transistors. However, shortening the gates' lengths may cause or exacerbate optical proximity effects, which may affect channel length consistency. On the other hand, reducing the horizontal distance may drive the photolithography process used beyond its ability. As a possible consequence of this, insufficient exposure may occur between the gates 130 of the first PD transistors and the gates 140 of the second PD transistors, potentially resulting in a short circuit. Thus, further shrinkage of the conventional SRAM layout structure is impossible because the horizontal lengths of the first PD transistors and/or the gates 140 of the second PD transistors could not be shortened within the ability of the photolithography process used.

### SUMMARY

It is an object of the present invention to provide a SRAM layout structure with a reduced SRAM layout area, which is achieved within the ability of the photolithography process used without reducing lengths of gates 130 of first PD transistors and/or gates 140 of second PD transistors.

To this end, the present invention provides a static random access memory (SRAM) layout structure including:
a first active area and a second active area isolated from the first active area by a STI structure, both the first and second active areas extending perpendicular to a horizontal direction;
a gate of a first PD transistor located on the first active area, the gate of the first PD transistor is divided into two portions: a first gate portion of the first PD transistor perpendicular to the direction of extension of the first active area; and a second gate portion of the first PD transistor joined to the first gate portion of the first PD transistor at an angle less than 180° clockwise with respect to the first gate portion of the first PD transistor; and
a gate of a second PD transistor located on the second active area, the gate of the second PD transistor is divided into two portions: a first gate portion of the second PD transistor perpendicular to the direction of extension of the second active area; and a second gate portion of the second PD transistor joined to the first gate portion of the second PD transistor at an angle less than 180° clockwise with respect to the first gate portion of the second PD transistor,
wherein the second gate portion of the second PD transistor and the second gate portion of the first PD transistor oppose each other, and are spaced apart from each other at a distance, which satisfies a photolithography requirement.

Optionally, the SRAM layout structure may further include a gate of a PG transistor, which bridges the first and second active areas.

Optionally, in the SRAM layout structure, minimum possible distances from the gate of the PG transistor respectively to the gate of the first PD transistor and the gate of the second PD transistor may both satisfy the photolithography requirement.

Optionally, in the SRAM layout structure, the second gate portion of the first PD transistor may be clockwise at an angle of 90°-165° with respect to the first gate portion of the first PD transistor.

Optionally, in the SRAM layout structure, the second gate portion of the second PD transistor may be clockwise at an angle of 90°-165° with respect to the first gate portion of the second PD transistor.

Optionally, in the SRAM layout structure, the angle that the second gate portion of the first PD transistor is clockwise at with respect to the first gate portion of the first PD transistor may be the same as, or different from, the angle that the second gate portion of the second PD transistor is clockwise at with respect to the first gate portion of the second PD transistor.

Optionally, in the SRAM layout structure, the second gate portion of the first PD transistor may have a width less than or equal to a width of the first gate portion of the first PD transistor.

Optionally, in the SRAM layout structure, the second gate portion of the second PD transistor may have a width less than or equal to a width of the first gate portion of the second PD transistor.

Optionally, in the SRAM layout structure, there may be at least two gates of respective first PD transistors, which are all spaced apart at a distance.

Optionally, in the SRAM layout structure, there may be at least two gates of respective second PD transistors, which are all spaced apart at a distance.

The present invention provides a SRAM layout structure including: a first active area and a second active area isolated from the first active area by a STI structure, both the first and second active areas extending perpendicular to a horizontal direction; a gate of a first PD transistor located on the first active area, the gate of the first PD transistor having two portions: a first gate portion of the first PD transistor perpendicular to the direction of extension of the first active area; and a second gate portion of the first PD transistor joined to the first gate portion of the first PD transistor at an angle less than 180° clockwise with respect to the first gate portion of the first PD transistor; and a gate of a second PD transistor located on the second active area, the gate of the second PD transistor having two portions: a first gate portion of the second PD transistor perpendicular to the direction of extension of the second active area; and a second gate portion of the second PD transistor joined to the first gate portion of the second PD transistor at an angle less than 180° clockwise with respect to the first gate portion of the second PD transistor, wherein the second gate portion of the second PD transistor and the second gate portion of the first PD transistor oppose each other, and are spaced apart from each other at a distance, which satisfies a photolithography requirement. According to the present invention, through dividing each of the gates of the first and second PD transistors into two portions forming an angle therebetween less than 180°, both the gates of the first and second PD transistors assume bent shapes, which allow for a shorter horizontal distance between the gates of the first and second PD transistors at given lengths of the gates while ensuring a spacing between the gates of the first and second PD transistors, which still satisfies the photolithography requirement. In this way, a smaller SRAM layout area can be obtained while satisfying the photolithography requirement, without reducing horizontal length(s) of the gate(s) of the first PD transistor and/or the second PD transistor.

### BRIEF DESCRIPTION OF THE DRAWINGS

FIG. 1 is a schematic illustration of a conventional SRAM layout structure.

FIG. 2 is a schematic illustration of a SRAM layout structure according to embodiments described herein.

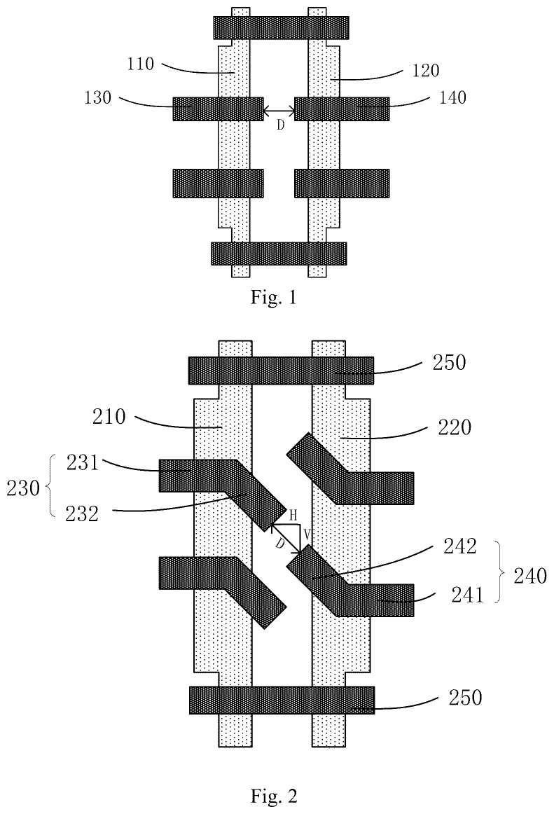

In these figures, 110 denotes a first active area; 120, second active area; 130, gate of first PD transistor; 140, gate of second PD transistor; 210, a first active area; 220, second active area; 230, gate of first PD transistor; 231, first gate portion of first PD transistor; 232, second gate portion of first PD transistor; 240, gate of second PD transistor, 241, first gate portion of second PD transistor, 242, second gate portion of second PD transistor; and 250, gate of PG transistor.

### DETAILED DESCRIPTION

Specific embodiments described herein will be described in greater detail below with reference to the accompanying drawings. From the following description, advantages and features of the present invention will become more apparent. Note that the figures are provided in a very simplified form not necessarily drawn to exact scale for the only purpose of helping to explain the disclosed embodiments in a more convenient and clearer way.

In the following, the terms “first”, “second” and the like may be used to distinguish between similar elements without necessarily implying any particular ordinal or chronological sequence. It will be understood that the terms so used are interchangeable, whenever appropriate. Likewise, if a method is described herein as including a series of steps, the order of these steps as presented herein is not necessarily the only order in which they can be performed, and some of the stated steps may be omitted and/or other steps not described herein may be added to the method.

It will be understood that when a layer (or film), region, pattern or structure is referred to as being “above” a substrate, other layer (or film), region and/or pattern, it may be directly on the other layer or substrate, or intervening layer(s) may also be present. It will also be understood that when a layer is referred to as being “under” another layer, it may be directly under or below the other layer, or one or more intervening layers may also be present. Further, reference to a layer being “above” or “under” another layer is made herein based on the orientation of the accompanying drawings.

Referring to FIG. 2, the present invention provides a static random access memory (SRAM) layout structure including:
a first active area 210 and a second active area 220. The first active area 210 and the second active area 220 are isolated by a shallow trench isolation (STI) structure, both the first active area 210 and the second active area 220 extending perpendicular to a horizontal direction;
a gate 230 of a first pull-down (PD) transistor located on the first active area 210, the gate 230 of the first PD transistor is divided into two portions: a first gate portion 231 of the first PD transistor perpendicular to the direction of extension of the first active area 210; and a second gate portion 232 of the first PD transistor joined to the first gate portion 231 of the first PD transistor at an angle less than 180° clockwise with respect to the first gate portion 231 of the first PD transistor; and
a gate 240 of a second PD transistor located on the second active area 220, the gate 240 of the second PD transistor is divided into two portions: a first gate portion 241 of the second PD transistor perpendicular to the direction of extension of the second active area 220; and a second gate portion 242 of the second PD transistor joined to the first gate portion 241 of the second PD transistor at an angle less than 180° clockwise with respect to the first gate portion 241 of the second PD transistor,
wherein the second gate portion 242 of the second PD transistor and the second gate portion 232 of the first PD transistor oppose each other, and are spaced apart from each other at a distance (referring to the vertical distance between the opposing end surfaces of the second gate portion 242 of the second PD transistor and the second gate portion 232 of the first PD transistor), which satisfies a photolithography requirement.

Preferably, according to embodiments described herein, the SRAM layout structure further includes a gate 250 of a pass-gate (PG) transistor, the gate 250 of the PG transistor bridges the first active area 210 and the second active area 220 and forms the PG transistor together with the first active area 210 and the second active area 220. Minimum possible distances from the gate 250 of the PG transistor respectively to the gate 230 of the first PD transistor and the gate 240 of the second PD transistor both satisfy the photolithography requirement. This is because the photolithography requirement must be met even in practical layout applications designed with the gate of the PG transistor. Specifically, referring to FIG. 2, according to embodiments described herein, there may be gates 250 of upper and lower PG transistors, and the second gate portion 232 of the first PD transistor and the second gate portion 242 of the second PD transistor may be closest to the gates 250 of the PG transistors. In such cases, both a minimum possible distance from the second gate portion 232 of the first PD transistor to the gates 250 of the PG transistors and a minimum possible distance from the second gate portion 242 of the second PD transistor to the gates 250 of the PG transistors must satisfy the photolithography requirement. The minimum possible distance may be measured between a point on an edge of the second gate portion 232 of the first PD transistor or on an edge of the second gate portion 242 of the second PD transistor and a point on an edge of a corresponding one of the gates 250 of the PG transistors. In other embodiments described herein, there may also be a gate oxide layer between the active areas and the gates of the PD transistors and spacers on both sides of the gates of the PD transistors. Likewise, there may also be a gate oxide layer between the active areas and the gate(s) of the PG transistor(s) and spacers on both sides of the gate(s) of the PG transistor(s).

According to embodiments described herein, the angle formed by the second gate portion 232 of the first PD transistor clockwise with respect to the first gate portion 231 of the first PD transistor may be 90°-165°, such as, for example, 135°, and the angle formed by the second gate portion 242 of the second PD transistor clockwise with respect to the first gate portion of the second PD transistor may be 90°-165°, such as, for example, 135°. The angle formed by the second gate portion 232 of the first PD transistor clockwise with respect to the first gate portion 231 of the first PD transistor may be equal to the angle formed by the second gate portion 242 of the second PD transistor clockwise with respect to the first gate portion 241 of the second PD transistor, or not.

According to embodiments described herein, the second gate portion 232 of the first PD transistor may have a width less than or equal to a width of the first gate portion 231 of the first PD transistor, and the second gate portion 242 of the second PD transistor may have a width less than or equal to a width of the first gate portion 241 of the second PD transistor.

According to embodiments described herein, there may be a number of gates 230 of respective first PD transistors, all of the gates 230 of the first PD transistors are spaced apart at a predetermined distance. In the case of at least two gates 230 of respective first PD transistors, the first active area 210 is exposed between adjacent gates 230 of the first PD transistors. Additionally, there may be a number of gates 240 of respective second PD transistors, all of the gates 240 of the second PD transistors are spaced apart at a predetermined distance. In the case of at least two gates 240 of respective second PD transistors, the second active area 220 is exposed between adjacent gates 240 of the second PD transistors. A plurality of PD transistors may be designed, and the number of them may vary from application to application, and may be one, two or more. Therefore, in embodiments herein, there may be a number of gates 230 of respective first PD transistors and a number of gates 240 of respective second PD transistors. All the gates 230 of the first PD transistors may be bent in the same direction, preferably at the same angle. All the gates 240 of the second PD transistors may be bent in an opposite direction with respect to the gates 230 of the first PD transistors, preferably at the same angle. Each gate 230 of the respective first PD transistor may include a first gate portion 231 of the first PD transistor and a second gate portion 232 of the first PD transistor. It is always the case that each gate 240 of the respective second PD transistor has an opposing portion. Each gate 240 of the respective second PD transistor may have a first gate portion 241 of the second PD transistor and a second gate portion 242 of the second PD transistor. Moreover, the second gate portions 232 of the first PD transistors may oppose the second gate portions 242 of the second PD transistors. It is a matter of course that any of the second gate portions 232 of the first PD transistors is spaced from any of the second gate portions 242 of the second PD transistors at a minimum possible distance between their opposing end faces, which satisfies the photolithography requirement. For the photolithography process used, if the opposing gate end faces of the first and second PD transistors are required to be spaced apart at a minimum possible perpendicular distance of D, as is conventional, then a minimum possible horizontal distance between the gates 230 of the first PD transistors and the gates 240 of the second PD transistors, as well as between the second gate portions 232 of the first PD transistors and the second gate portions 242 of the second PD transistors, denoted as H, will be less than D for sure. That is, the minimum possible horizontal distance between the gates 230 of the first PD transistors and the gates 240 of the second PD transistors is allowed to be made shorter than that of the conventional one. This advantage is achieved because, at given horizontal lengths of the gates 230 of the first PD transistors and the gates 240 of the second PD transistors, bending them means a shorter minimum possible horizontal distance between them. Therefore, compared with the prior art, embodiments described herein enable a smaller SRAM area at given lengths of the gates 230 of the first PD transistors and the gates 240 of the second PD transistors and a given distance between their opposing end faces, which satisfies the photolithography requirement.

To conclude, embodiments described herein provide a SRAM layout structure including: a first active area and a second active area isolated from the first active area by a STI structure, both the first and second active areas extending perpendicular to a horizontal direction; a gate of a first PD transistor located on the first active area, the gate of the first PD transistor having two portions: a first gate portion of the first PD transistor perpendicular to the direction of extension of the first active area; and a second gate portion of the first PD transistor joined to the first gate portion of the first PD transistor at an angle less than 180° clockwise with respect to the first gate portion of the first PD transistor; and a gate of a second PD transistor located on the second active area, the gate of the second PD transistor having two portions: a first gate portion of the second PD transistor perpendicular to the direction of extension of the second active area; and a second gate portion of the second PD transistor joined to the first gate portion of the second PD transistor at an angle less than 180° clockwise with respect to the first gate portion of the second PD transistor, wherein the second gate portion of the second PD transistor and the second gate portion of the first PD transistor oppose each other, and are spaced apart from each other at a distance, which satisfies a photolithography requirement. According to the present invention, through dividing each of the gates of the first and second PD transistors into two portions forming an angle therebetween less than 180°, both the gates of the first and second PD transistors assume bent shapes, which allow for a shorter horizontal distance between the gates of the first and second PD transistors at given lengths of the gates while ensuring a spacing between the gates of the first and second PD transistors, which still satisfies the photolithography requirement. In this way, a smaller SRAM layout area can be obtained while satisfying the photolithography requirement, without reducing horizontal length(s) of the gate(s) of the first PD transistor and/or the second PD transistor.

Presented above are merely a few preferred embodiments described herein, which do not limit the invention in any way. Changes in any forms made to the principles and teachings disclosed herein, including equivalents and modifications, by any person of ordinary skill in the art without departing from the scope of the invention are intended to fall within the scope of the invention.

1. A layout structure of a static random access memory, comprising:
a first active area and a second active area, wherein the first active area and the second active area are isolated by a shallow trench isolation structure, both the first active area and the second active area extending perpendicular to a horizontal direction;
a gate of a first pull-down (PD) transistor located on the first active area, the gate of the first PD transistor is divided into two portions: a first gate portion of the first PD transistor perpendicular to the direction of extension of the first active area; and a second gate portion of the first PD transistor joined to the first gate portion of the first PD transistor at an angle less than 180° clockwise with respect to the first gate portion of the first PD transistor; and
a gate of a second PD transistor located on the second active area, the gate of the second PD transistor is divided into two portions: a first gate portion of the second PD transistor perpendicular to the direction of extension of the second active area; and a second gate portion of the second PD transistor joined to the first gate portion of the second PD transistor at an angle less than 180° clockwise with respect to the first gate portion of the second PD transistor,
wherein the second gate portion of the second PD transistor and the second gate portion of the first PD transistor oppose each other, and are spaced apart from each other at a distance, which satisfies a photolithography requirement.

2. The layout structure of the static random access memory of claim 1, further comprising a gate of a pass-gate (PG) transistor, which bridges the first active area and the second active area.

3. The layout structure of the static random access memory of claim 2, wherein minimum possible distances from the gate of the PG transistor respectively to the gate of the first PD transistor and the gate of the second PD transistor both satisfy the photolithography requirement.

4. The layout structure of the static random access memory of claim 1, wherein the second gate portion of the first PD transistor is clockwise at an angle of 90°-165° with respect to the first gate portion of the first PD transistor.

5. The layout structure of the static random access memory of claim 1, wherein the second gate portion of the second PD transistor is clockwise at an angle of 90°-165° with respect to the first gate portion of the second PD transistor.

6. The layout structure of the static random access memory of claim 1, wherein the angle that the second gate portion of the first PD transistor is clockwise at with respect to the first gate portion of the first PD transistor is the same as the angle that the second gate portion of the second PD transistor is clockwise at with respect to the first gate portion of the second PD transistor.

7. The layout structure of the static random access memory of claim 1, wherein the angle that the second gate portion of the first PD transistor is clockwise at with respect to the first gate portion of the first PD transistor is different from the angle that the second gate portion of the second PD transistor is clockwise at with respect to the first gate portion of the second PD transistor.

8. The layout structure of the static random access memory of claim 1, wherein the second gate portion of the first PD transistor has a width less than or equal to a width of the first gate portion of the first PD transistor.

9. The layout structure of the static random access memory of claim 1, wherein the second gate portion of the second PD transistor has a width less than or equal to a width of the first gate portion of the second PD transistor.

10. The layout structure of the static random access memory of claim 1, wherein there are at least two gates of respective first PD transistors, and all gates of the first PD transistors are spaced apart at a distance.

11. The layout structure of the static random access memory of claim 1, wherein there are at least two gates of respective second PD transistors, and all gates of the second PD transistors are spaced apart at a distance.

12. The layout structure of the static random access memory of claim 10, wherein the gates of the first PD transistors are all bent in the same direction at the same angle.

13. The layout structure of the static random access memory of claim 12, wherein there are at least two gates of respective second PD transistors, which are bent in a direction opposite to the direction in which the gates of the first PD transistors are bent.
